(19) United States
(12) Patent Application Publication
(10) Pub. No.: US 2022/0199376 A1
(43) Pub. Date: Jun. 23, 2022

(54) Workpiece Processing Apparatus with Vacuum Anneal Reflector Control

(71) Applicants: Mattson Technology, Inc., Fremont, CA (US); Beijing E-Town Semiconductor Technology Co., Ltd., Beijing (CN)

(72) Inventors: Michael Yang, Palo Alto, CA (US); Manuel Sohn, Neu-Ulm (DE); Rolf Bremensdorfer, Bibertal (DE)

(21) Appl. No.: 17/549,096

(22) Filed: Dec. 13, 2021

Related U.S. Application Data
(60) Provisional application No. 63/129,108, filed on Dec. 22, 2020.

(51) Int. Cl. H01J 37/32; H01L 21/268; H01L 21/66

(52) U.S. Cl. CPC H01J 37/32724; H01J 37/3244; H01J 37/32834; H01J 2237/20214; H01L 22/20; H01J 2237/2001; H01L 21/2686

(57) ABSTRACT

A workpiece processing apparatus is provided. The workpiece processing apparatus can include a processing chamber and a workpiece disposed on a workpiece support within the processing chamber. The workpiece processing apparatus can include a gas delivery system and one or more exhaust ports for removing gas from the processing chamber such that a vacuum pressure can be maintained. The workpiece processing apparatus can include radiative heating sources configured to heat the workpiece. The workpiece processing apparatus can further include a plurality of reflectors. The workpiece processing apparatus can include a control system configured to control one or more positions of the reflectors.

### PRIORITY CLAIM

The present application claims the benefit of priority of U.S. Provisional Application Ser. No. 63/129,108, titled “Workpiece Processing Apparatus with Vacuum Anneal Reflector Control,” filed on Dec. 22, 2020, which is incorporated herein by reference.

### FIELD

The present disclosure relates generally to semiconductor processing equipment, such as equipment operable to perform thermal processing of a workpiece.

### BACKGROUND

A workpiece processing apparatus (e.g., thermal processing system) can define a processing chamber configured to accommodate a workpiece, such as a semiconductor wafer. During thermal processing, the workpiece can be heated inside the processing chamber. Non-uniformities in the temperature of the workpiece can develop as the temperature of the workpiece increases, which can lead to anomalies or other defects associated with the workpiece.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a workpiece processing apparatus according to example embodiments of the present disclosure;

FIG. 2 depicts a reflector array of a workpiece processing apparatus according to example embodiments of the present disclosure;

FIG. 3 depicts heating zones corresponding to radiation applied onto a back side of a workpiece according to example aspects of the present disclosure;

FIG. 4 depicts radiation applied onto a back side of a workpiece according to example aspects of the present disclosure;

FIG. 5 depicts a flow diagram of a method for controlling operation of a workpiece processing apparatus according to example embodiments of the present disclosure;

FIG. 6 depicts a flow diagram of a method for controlling operation of a workpiece processing apparatus according to example embodiments of the present disclosure;

FIG. 7 depicts a workpiece processing apparatus according to example embodiments of the present disclosure;

FIG. 8 depicts a reflector array of a workpiece processing apparatus according to example embodiments of the present disclosure;

FIG. 9 depicts a workpiece processing apparatus according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to systems and methods for thermal processing of a workpiece. Controlling temperature uniformity of a workpiece during thermal processing is important to reduce defects and other non-uniformities associated with the workpiece. In typical thermal processing systems, a workpiece is rotated to increase uniform application of radiation emitted from radiative heating sources. In thermal processing systems where it is desirable to maintain a vacuum, it can be difficult to rotate the workpiece. Furthermore, in processing systems that use traditional stationary sensors to measure temperatures of the workpiece, it can be difficult to obtain a temperature profile of the workpiece without rotating the workpiece past the stationary sensors. In that regard, it can be more difficult to maintain temperature uniformity of the workpiece.

According to example aspects of the present disclosure, a workpiece processing apparatus (e.g., a workpiece processing apparatus in which a vacuum is maintained during a thermal treatment process) includes a control system configured to adjust the positions of reflectors to control the application of radiation onto a workpiece to compensate for the lack of a rotation system configured to rotate the workpiece. According to example aspects of the present disclosure, the workpiece processing apparatus can include controllable reflectors configured to direct radiation emitted from radiative heating sources disposed between the workpiece and the reflectors. The reflectors can be in a generally perpendicular relationship, such as within about 20 degrees of perpendicular, to the radiative heating sources such that radiation is applied to a back side of the workpiece in a grid-like pattern. For example, the radiative heating sources can emit radiation onto the back side of the workpiece along a y-axis of the grid-like pattern, and the reflectors can direct radiation onto the back side of the workpiece along an x-axis of the grid-like pattern. The generally perpendicular relationship between the radiative heating sources and the reflectors can be controlled as “pixels” of radiation onto the back side of the workpiece. Furthermore, the control system is able to control the pixels of radiation by adjusting the positions of the reflectors. In this manner, the workpiece processing apparatus according to example aspects of the present disclosure allows for an improved capability of directing radiation onto portions of the workpiece as needed for maintaining temperature uniformity of the workpiece.

In addition, the control system is able to control the reflectors based, at least in part, on data indicative of a temperature profile of the workpiece in order to increase uniform application of radiation onto the workpiece. For instance, by obtaining temperature measurements across the workpiece, the control system can detect whether one portion of the workpiece is at a higher temperature relative to another portion of the workpiece. In response, the control system can adjust the positions of the reflectors to reduce the amount of radiation directed onto the portion having a higher temperature. Alternatively, the control system can obtain temperature measurements indicating that one portion of the workpiece is at a lower temperature relative to another portion of the workpiece. Accordingly, the control system can adjust the positions of the reflectors to increase the amount of radiation directed onto the portion of the workpiece having a lower temperature. In this manner, the control system can maintain temperature uniformity without rotating the workpiece during thermal treatments by controlling the reflectors directing radiation onto the back side of the workpiece based, at least in part, on the temperature profile of the workpiece.

In accordance with some embodiments of the present disclosure, the workpiece processing apparatus can be configured to rotate a workpiece support, if desired, while maintaining a vacuum pressure inside the processing chamber. The workpiece processing apparatus can include controllable reflectors configured to direct heat emitted from radiative heating sources disposed between the workpiece support and the reflectors. The reflectors can be in a generally parallel relationship, such as within about 20 degrees of parallel, to the radiative heating sources such that a rotation shaft can be coupled onto an end of a workpiece support. The workpiece processing apparatus can rotate the workpiece support past stationary sensors to obtain a temperature profile of a workpiece disposed on the workpiece support and adjust the reflectors based, at least in part, on temperature differentials associated with portions of the workpiece. In addition, due to the generally parallel relationship between the reflectors and radiative heating sources, an increased amount of radiation can be applied toward the portion of the workpiece support to which the rotation shaft is coupled. In this manner, the workpiece processing apparatus can maintain temperature uniformity by controlling the positions of reflectors that have a generally parallel relationship to the radiative heating sources.

Example aspects of the present disclosure provide a number of technical effects and benefits. For instance, by controlling the reflectors in the manner disclosed in the present application, thermal uniformity can be improved by simulation of rotation of the workpiece in situations where it can be difficult to rotate the workpiece such as, for example, when it is maintained in a vacuum. In this manner, defects and other non-uniformities in the workpiece that are attributable to a lack of uniform application of heat emitted from radiative heating sources can be reduced. In addition, the workpiece processing apparatus can be configured to obtain a temperature profile of the workpiece and control the positions of the reflectors directing radiation onto the workpiece based, at least in part, on the temperature profile.

Aspects of the present disclosure are discussed with reference to a “workpiece” or “wafer” or semiconductor wafer for purposes of illustration and discussion. As used herein, the use of the term “about” in conjunction with a numerical value is intended to refer to within 20% of the stated amount. In addition, the terms “first,” “second,” and “third” may be used interchangeably to distinguish one component from another and are not intended to signify location or importance of the individual components.

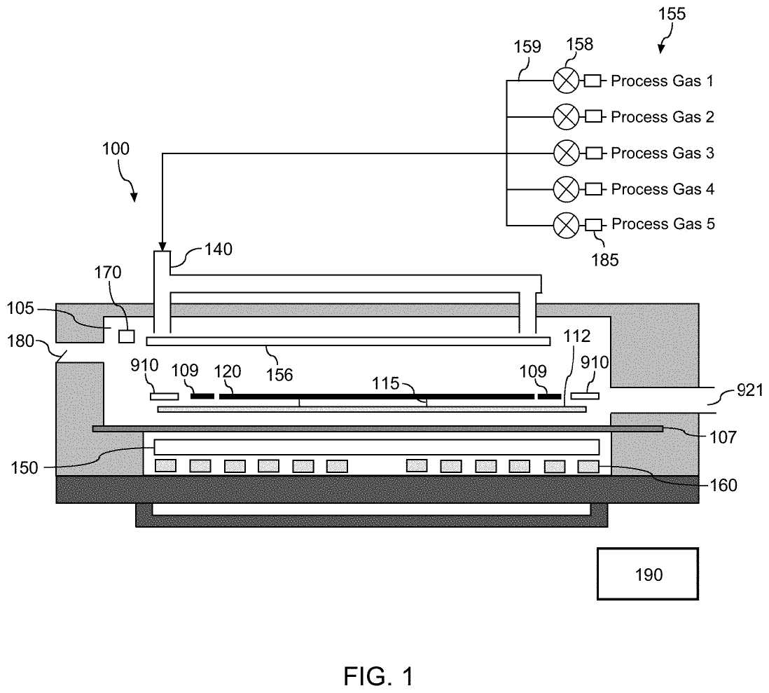

With reference now to the FIGS., example embodiments of the present disclosure will be discussed in detail. FIGS. 1-4 depict various aspects of a workpiece processing apparatus 100 according to example embodiments of the present disclosure. As shown in FIG. 1, the workpiece processing apparatus 100 can include a gas delivery system 155 configured to deliver process gas to a processing chamber 105, for instance, via a gas distribution channel 140. The gas delivery system can include a plurality of feed gas lines 159. The feed gas lines 159 can be controlled using valves 158 and/or gas flow controllers 185 to deliver a desired amount of gases into the processing chamber as process gas.

The gas delivery system 155 can be used for the delivery of any suitable process gas. Example process gases include, oxygen-containing gases (e.g., O₂, O₃, N₂O, H₂O), hydrogen-containing gases (e.g., H₂, D₂), nitrogen-containing gas (e.g., N₂, NH₃, N₂O), fluorine-containing gases (e.g., CF₄, C₂F₄, CHF₃, CH₂F₂, CH₃F, SF₆, NF₃), hydrocarbon-containing gases (e.g., CH₄), or combinations thereof. Other feed gas lines containing other gases can be added as needed. In some embodiments, the process gas can be mixed with an inert gas that can be called a “carrier” gas, such as He, Ar, Ne, Xe, or N₂.

The gases discussed with reference to FIG. 1 are provided for example purposes only. Those of ordinary skill in the art, using the disclosures provided herein, will understand that any suitable process gas can be used without deviating from the scope of the present disclosure.

As shown in FIG. 1, the workpiece processing apparatus 100 can include one or more gas distribution plates 156 disposed about the first side, such as a top side, of the processing chamber 105. The first side of the processing chamber 105 can be opposite from a second side, such as a bottom side, of the processing chamber 105. The one or more gas distribution plates 156 can be used to more uniformly disperse process gases in the processing chamber 105. Process gases can be delivered by the distribution channel 140 and pass through one or more gas distribution plates 156 to more uniformly and evenly distribute gas in the processing chamber 105, thus ensuring that the top side of the workpiece 120 is uniformly exposed to process gases. In embodiments, the gas distribution plates can include a plurality of apertures or channels configured to facilitate uniform distribution of process gases in the processing chamber 105.

As further illustrated in FIG. 1, one or more exhaust ports 921 disposed in the processing chamber 105 are configured to pump gas out of the processing chamber 105, such that a vacuum pressure can be maintained in the processing chamber 105. For example, the process gas exposed to the workpiece 120 can flow around either side of the workpiece 120 and can be evacuated from the processing chamber 105 via one or more exhaust ports 921. One or more pumping plates 910 can be disposed around the outer perimeter of the workpiece 120 to facilitate process gas flow. Isolation door 180, when open, allows entry of the workpiece 120 to the processing chamber 105 and, when closed, allows the processing chamber 105 to be sealed, such that a vacuum pressure can be maintained in the processing chamber 105 during thermal processing of workpiece 120.

As depicted in FIG. 1, the workpiece 120 to be processed is supported in the processing chamber 105 by the workpiece support 112. The workpiece 120 can be or include any suitable workpiece, such as a semiconductor workpiece, such as a silicon wafer. In some implementations, the workpiece can be a semiconductor wafer. It should be appreciated, however, that the semiconductor wafer can be formed from any suitable type of semiconductor material. Examples of semiconductor material from which the semiconductor wafer is formed can include, without limitation, silicon, germanium, or III-V semiconductor. However, other suitable workpieces can be used without deviating from the scope of the present disclosure.

In some implementations, a workpiece support 112 can be or include any suitable support structure configured to support the workpiece 120 in the processing chamber 105. For example, the workpiece support 112 can be a workpiece support 112 operable to support the workpiece 120 during thermal processing. In some embodiments, workpiece support 112 can be configured to support a plurality of workpieces 120 for simultaneous thermal processing by a workpiece processing apparatus. The workpiece support 112 can be transparent to and/or otherwise configured to allow at least some radiation to at least partially pass through the workpiece support 112. In some embodiments, the workpiece support 112 can be or include a quartz material, such as a hydroxyl free quartz material.

As shown in FIG. 1, a guard ring 109 can be used to lessen edge effects of radiation from one or more edges of the workpiece 120. The guard ring 109 can be disposed around the workpiece 120. Further, in embodiments, the processing apparatus includes a pumping plate 910 disposed around the workpiece 120 and/or the guard ring 109. For example, the pumping plate 910 can include one or more pumping channels for facilitating the flow of gas through the processing chamber 105. The pumping plate 910 can be or include a quartz material. Furthermore, in some embodiments, the pumping plate 910 can be or include quartz containing a significant level of hydroxyl (OH) groups, a.k.a. hydroxyl doped quartz.

As further illustrated in FIG. 1, workpiece support 112 can include one or more support pins 115, such as at least three support pins, extending from the workpiece support 112. In some embodiments, workpiece support 112 can be spaced from the top of the processing chamber 105. In some embodiments, the support pins 115 and/or the workpiece support 112 can transmit heat from heat sources 150 and/or absorb heat from workpiece 120. In some embodiments, the support pins 115 can be made of quartz.

According to example aspects of the present disclosure, a dielectric window 107 can be disposed between the workpiece support 112 and radiative heating sources 150. Dielectric window 107 can be configured to selectively block at least a portion of radiation emitted by radiative heating sources 150 from entering a portion of the processing chamber 105. In some embodiments, the dielectric window 107 can be or include hydroxyl (OH) containing quartz, such as hydroxyl (OH—) doped quartz, and/or can be or include hydroxyl free quartz.

The workpiece processing apparatus 100 can include one or more radiative heating sources 150. In some embodiments, one of the radiative heating sources 150 can be disposed about a second side of the processing chamber 105, such as the bottom side of the processing chamber 105. Accordingly, radiative heating sources 150 can emit radiation onto a surface, such as a second surface, such as a back side, of the workpiece 120. For example, the back side of the workpiece 120 can face the workpiece support 112.

The workpiece processing apparatus 100 can include directive elements, such as, for example, a plurality of reflectors 160 (e.g., mirrors). In some embodiments, the plurality of reflectors 160 can be disposed about a second side of the processing chamber 105, such as the bottom side of the processing chamber. As shown in FIG. 1, the radiative heating sources 150 can be positioned between the workpiece 120 and the plurality of reflectors 160. For instance, the radiative heating sources 150 can be disposed at a first distance from a back side of the workpiece, and the plurality of reflectors 160 can be disposed at a second distance from the back side of the workpiece such that the second distance is greater than the first distance. In some embodiments, the plurality of reflectors 160 can direct radiation toward the workpiece 120 and/or workpiece support 112 to heat the workpiece 120. For example, the plurality of reflectors 160 can direct radiation emitted from heat sources 150 onto a surface, such as the back side, of the workpiece 120.

As depicted in FIG. 1, the workpiece processing apparatus 100 can include a thermal camera 170 (e.g., infrared camera) configured to obtain thermal image data (e.g., infrared image data) indicative of a temperature profile associated with the workpiece 120. The temperature profile can be indicative of a spatial distribution of temperature across the workpiece. For example, the temperature profile can indicate a first temperature at a first location on the workpiece and can further indicate a second temperature at a second location on the workpiece that is different from the first location.

In some implementations, the thermal camera 170 can include a complementary metal-oxide-semiconductor (CMOS) camera. It should be appreciated, however, that the camera can include any suitable type of camera configured to obtain thermal image data indicative of one or more non-uniformities in the temperature profile associated with the workpiece 120. In some implementations, the thermal camera 170 can have a shutter speed of about one thousand frames per second. In alternative implementations, the thermal camera 170 can have a shutter speed of about ten thousand frames per second. It should also be appreciated that a lens of the thermal camera 170 can have any suitable focal length. For instance, in some implementations, the focal length of the lens can be less than about 30 centimeters. In alternative implementations, the focal length of the lens can be less than about 10 centimeters.

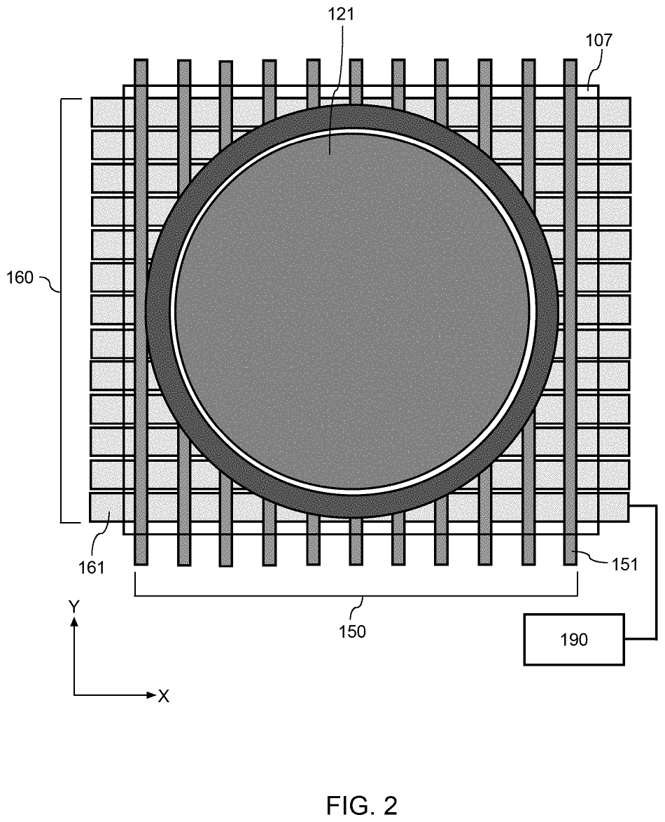

As shown in FIG. 1, the workpiece processing apparatus 100 can include a controller 190. As will be discussed below in more detail, the controller 190 is configured to adjust one or more positions of the plurality of reflectors 160 to maintain temperature uniformity of the workpiece 120. For example, the controller 190 can control the plurality of reflectors 160 via a connection line (depicted in FIG. 2) or other suitable wired and/or wireless interface. According to example aspects of the present disclosure, the controller 190 can include sensors (e.g., thermal cameras, pyrometers, emitters, and/or receivers) configured to obtain data indicative of a temperature profile associated with the workpiece 120. In this manner, defects and other non-uniformities in the workpiece 120 that are attributable to non-uniform radiation being applied to the workpiece 120 can be reduced with or without rotating the workpiece 120 in the processing chamber 105 while a vacuum is maintained.

Referring now to FIG. 2, the radiative heating sources 150 can be disposed with respect to the plurality of reflectors 160 to increase uniform application of radiation to the workpiece 120. FIG. 2 depicts a top view of the workpiece 120 with a top surface, such as a front side 121, of the workpiece 120 shown and with the dielectric window 107 disposed underneath the workpiece 120. Radiative heating sources 150 can include one or more heat lamps, such as heat lamp 151, configured to emit thermal radiation toward a surface, such as back side, of the workpiece 120 to heat the workpiece 120 during thermal processing. In some embodiments, for example, the heat lamp 151 can be any broadband radiation source including an arc lamp, incandescent lamp, halogen lamp, any other suitable heat lamp, or combinations thereof. In some embodiments, the heat lamp 151 can be a monochromatic radiation source including a light-emitting iodide, laser iodide, any other suitable heat lamp, or combinations thereof.

As shown in FIG. 2, the radiative heating sources 150 can include an array of heat lamps 151 disposed in a generally parallel relationship. For instance, each heat lamp 151 of the radiative heating sources 150 can be in a generally parallel relationship, such as within 20 degrees of parallel, such as within 5 degrees of parallel, such as within 0.1 degrees of parallel.

As depicted in FIG. 2, the plurality of reflectors 160 can include an array of controllable reflectors 161 disposed in a generally parallel relationship. For example, each controllable reflector 161 of the plurality of reflectors 160 can be in a generally parallel relationship, such as within 20 degrees of parallel, such as within 5 degrees of parallel, such as within 0.1 degrees of parallel. In some embodiments, one or more of the controllable reflectors 161 can be connected to the controller 190 via a connection line or other suitable wired and/or wireless interface.

As further illustrated in FIG. 2, the radiative heating sources 150 can be in a generally perpendicular relationship, such as within 20 degrees of perpendicular, such as within 5 degrees of perpendicular, such as within 0.1 degrees of perpendicular, to the plurality of reflectors 160. For example, the one or more radiative heating sources 150 can extend in a first direction corresponding to a y-axis, and the plurality of reflectors 160 can extend in a second direction corresponding to an x-axis. The first direction can be generally orthogonal to the second direction.

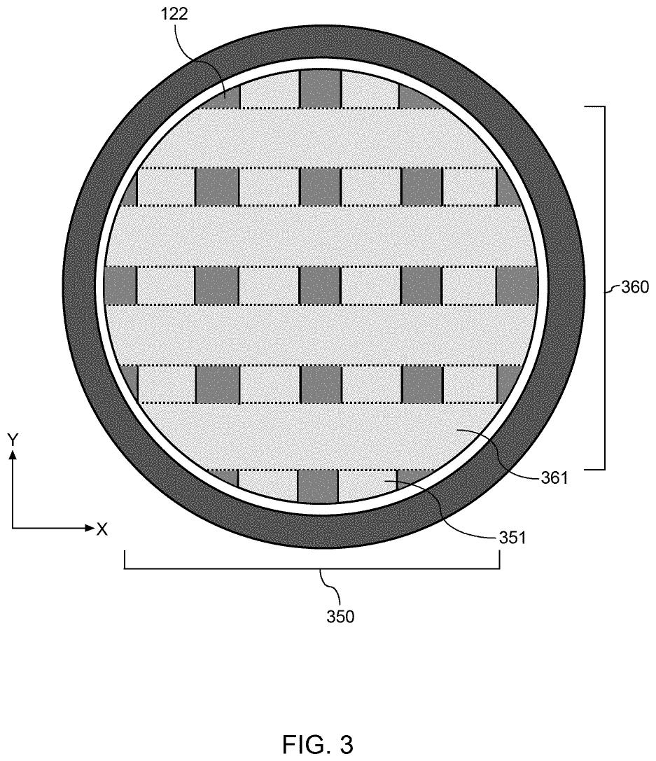

FIG. 3 depicts heating zones corresponding to radiation applied to a surface of the workpiece 120. Referring to FIGS. 2-3, the radiative heating sources 150 comprising an array of heat lamps 151 can emit radiation to heat different zones, such as radiation heat zones 350, of the workpiece 120. For instance, heat lamp 151 can emit radiation toward a back side 122 of the workpiece 120 to heat a radiation heat zone 351. Furthermore, radiation directed by reflectors 160 including an array of controllable reflectors 161 can heat different zones, such as reflection heat zones 360, of the workpiece 120. For example, controllable reflector 161 can direct radiation toward the back side 122 of the workpiece 120 to heat a reflection heat zone 361.

In some embodiments, radiation can be applied to the back side 122 of the workpiece 120 in a grid-like pattern. For instance, the radiative heating sources 150 can be in a generally perpendicular relationship, such as within 20 degrees of perpendicular, such as within 5 degrees of perpendicular, such as within 0.1 degrees of perpendicular, to the plurality of reflectors 160. The radiative heating sources 150 can emit radiation onto the back side 122 of the workpiece 120 along a y-axis to heat the workpiece at radiation heat zones 350. Similarly, the plurality of reflectors 160 can direct radiation onto the back side 122 of the workpiece 120 along an x-axis to heat the workpiece at reflection heat zones 360. In this manner, radiation emitted from the radiative heating sources 150 and radiation directed from the reflectors 160 can be controlled as “pixels” of radiation onto the back side 122 of the workpiece 120 to heat the workpiece 120. In some embodiments, the pixels of radiation can be controlled by adjusting one or more positions of the controllable reflectors 161, controlling amounts of radiation emitted from the radiative heating sources 150, and/or controlling types of radiation emitted from the radiative heating sources 150.

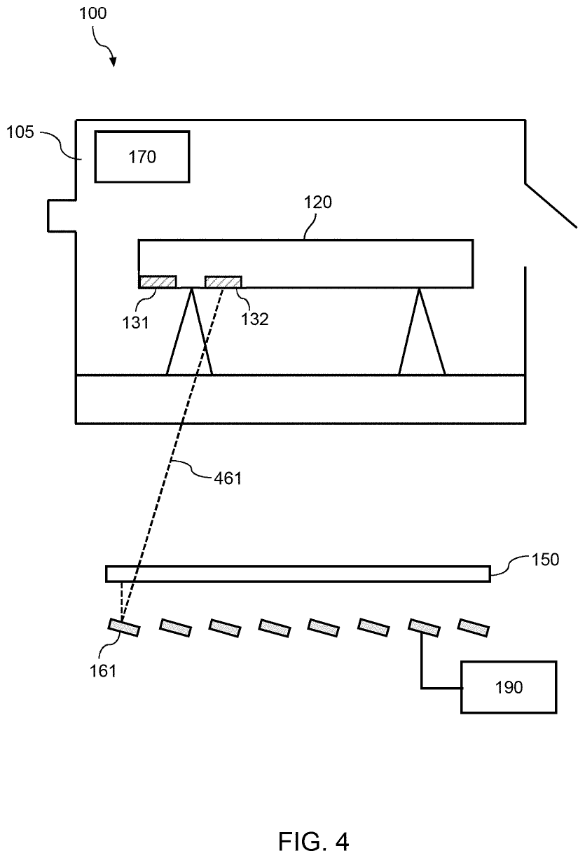

FIG. 4 depicts a simplified embodiment of the processing apparatus 100. As shown in FIG. 4, the plurality of reflectors can direct radiation emitted by the radiative heating sources 150 onto different portions of the workpiece 120. For instance, controllable reflector 161 can direct an amount of radiation 461 toward a portion, such as a second portion 132, of the workpiece 120. The thermal image data (e.g., infrared image data) obtained by a thermal camera 170 (e.g., infrared camera) can be indicative of a temperature profile associated with the workpiece 120. For example, the data can indicate a portion, such as a first portion 131, of the workpiece 120 is at a higher temperature relative to a remaining portion, such as the second portion 132, of the workpiece 120. Alternatively, the thermal image data can indicate that the first portion 131 of the workpiece 120 is at a lower temperature relative to the second portion 132 of the workpiece 120. The controller, which can be connected to one or more of controllable reflectors 161 via a connection line or other suitable wired and/or wireless interface, can adjust the positions of the controllable reflectors 161 based, at least in part, on the temperature profile associated with the workpiece 120 to increase uniform application of radiation onto the workpiece 120 without rotating the workpiece 120 while a vacuum is maintained in the processing chamber 105.

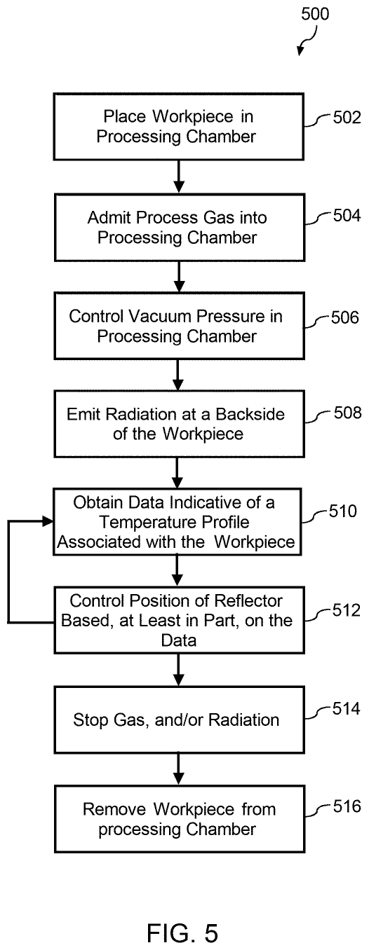

FIG. 5 depicts a flow diagram of one example method (500) according to example aspects of the present disclosure. The method (500) will be discussed with reference to the processing apparatus 100 of FIGS. 1-4 by way of example. The method (500) can be implemented in any suitable processing apparatus. FIG. 5 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (502), the method 500 can include placing the workpiece 120 in the processing chamber 105 of the processing apparatus 100. For instance, the method can include placing the workpiece 120 onto workpiece support 112 in the processing chamber 105 of FIG. 1. The workpiece 120 can include one or more layers comprising silicon, silicon dioxide, silicon carbide, one or more metals, one or more dielectric materials, or combinations thereof

At (504), the method 500 includes admitting a process gas to the processing chamber 105. For example, a process gas can be admitted to the processing chamber 105 via the gas delivery system 155 including a gas distribution channel 140. In some embodiments, the process gas can include oxygen-containing gases (e.g., O₂, O₃, N₂O, H₂O), hydrogen-containing gases (e.g., H₂, D₂), nitrogen-containing gases (e.g., N₂, NH₃, N₂O), fluorine-containing gases (e.g., CF₄, C₂F₄, CHF₃, CH₂F₂, CH₃F, SF₆, NF₃), hydrocarbon-containing gases (e.g., CH₄), or combinations thereof. In some embodiments, the process gas can be mixed with an inert gas, such as a carrier gas, such as He, Ar, Ne, Xe, or N₂. The control valve 158 can be used to control a flow rate of each feed gas line to flow a process gas into the processing chamber 105. Additionally or alternatively, the gas flow controller 185 can be used to control the flow of process gas.

The gases discussed with reference to method 500 are provided for example purposes only. Those of ordinary skill in the art, using the disclosures provided herein, will understand that any suitable process gas can be used without deviating from the scope of the present disclosure.

At (506) the method 500 includes controlling a vacuum pressure in the processing chamber 105. For example, one or more gases can be evacuated from the processing chamber 105 via the one or more gas exhaust ports 921. Further, the controller 190 can also implement one or more process parameters, altering conditions of the processing chamber 105 in order to maintain a vacuum pressure in the processing chamber 105 during thermal processing of the workpiece 120. For example, as process gases are introduced in the processing chamber 105, controller 190 can implement instructions to remove process gases from the processing chamber 105, such that a desired vacuum pressure can be maintained in the processing chamber 105. The controller 190 can include, for instance, one or more processors and one or more memory devices. The one or more memory devices can store computer-readable instructions that, when executed by the one or more processors, cause the one or more processors to perform operations, such as any of the control operations described herein.

At (508) the method 500 includes emitting radiation directed at one or more surfaces of the workpiece, such as a back side 122 of the workpiece 120, to heat the workpiece 120. For example, radiative heating sources 150 including one or more heat lamps 151 can emit thermal radiation to heat workpiece 120. In certain embodiments, directive elements, such as for example, the plurality of reflectors 160 (e.g., mirrors) can be configured to direct thermal radiation emitted from the radiative heating sources toward the workpiece 120 and/or workpiece support 112. The radiative heating sources 150 can be disposed on the bottom side of the processing chamber 105 in order to emit radiation at the back side 122 of the workpiece 120 when it is atop the workpiece support 112.

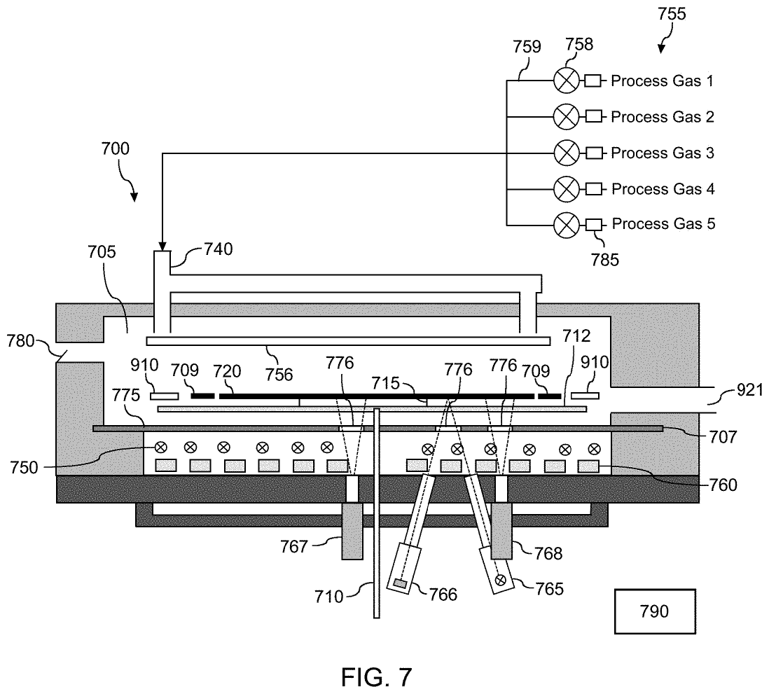

At (510), the method 500 includes obtaining data indicative of a temperature profile associated with the workpiece 120. In example embodiments, the data can be obtained from a thermal camera 170 configured to obtain thermal image data (e.g., infrared image data) indicative of a temperature profile associated with the workpiece 120. Alternatively or additionally, as depicted in FIG. 7 discussed below, the data can be obtained from one or more sensors including pyrometers 767,768, emitters 765, and/or receivers 766 configured to obtain data indicative of a temperature profile associated with a surface of a workpiece 720.

At (512), the method 500 includes controlling the positions of the plurality of reflectors 160 based, at least in part, on the data obtained at (510). As will be discussed below in more detail, the data obtained at (510) can indicate whether a first portion of the workpiece is at a higher or lower temperature relative to a second portion of the workpiece. Based on this data, the controller 190 can adjust the positions of the reflectors 160 to maintain temperature uniformity of the workpiece 120 during thermal processing.

At (514), process gas flow into the processing chamber 105 is stopped and radiation emittance of radiative heating sources 150 is stopped, thus ending workpiece processing.

At (516), the method 500 includes removing the workpiece 120 from the processing chamber 105. For instance, the workpiece 120 can be removed from the workpiece support 112 in processing chamber 105. The processing apparatus 100 can then be conditioned for future processing of additional workpieces.

In embodiments, the method depicted in FIG. 5 can include the listed steps in a variety of orders or combinations. For example, in certain embodiments the workpiece 120 is placed in the processing chamber 105 and exposed to radiation prior to admitting a process gas into the processing chamber 105. Process gas can be admitted into the processing chamber 105 while radiation is emitted at the back side 122 of the workpiece 120. Further, a vacuum pressure can be maintained in the processing chamber 105 while process gas is admitted to the processing chamber 105, while radiation is emitted at the back side of the workpiece 120, and/or while temperature measurements are obtained.

Furthermore, according to example aspects of the present disclosure, as depicted in FIG. 7 discussed below, a workpiece 720 can be rotated in a processing chamber 705 during thermal processing of the workpiece 720. The workpiece can be rotated as an additional and/or alternative step to the method 500 depicted in FIG. 5.

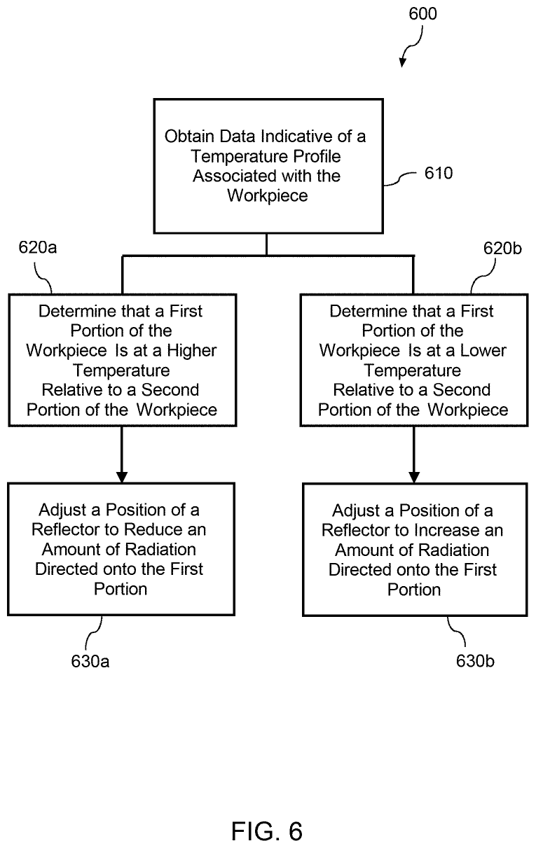

FIG. 6 depicts a flow diagram of a method for controlling operation of a processing system according to example embodiments of the present disclosure. It should be appreciated that the method 600 can be implemented using the workpiece processing apparatus 100 discussed with reference to FIGS. 1-4. FIG. 6 depicts steps performed in a particular order for purposes of illustration and discussion. Those of ordinary skill in the art, using the disclosures provided herein, will understand that various steps of the method 600 may be adapted, modified, rearranged, performed simultaneously or modified in various ways without deviating from the scope of the present disclosure.

At (610), the method 600 can include obtaining, by a controller of the workpiece processing apparatus, data indicative of a temperature profile associated with a workpiece disposed within a processing chamber. In example embodiments, the data can be obtained from the thermal camera 170 configured to obtain thermal image data (e.g., infrared image data) indicative of a temperature profile associated with the workpiece 120. Alternatively or additionally, as depicted in FIG. 7 discussed below, the data can be obtained from one or more sensors including pyrometers 767,768, emitters 765, and/or receivers 766 configured to obtain data indicative of a temperature profile associated with a surface of a workpiece 720.

At (620a), the method 600 can include determining that a first portion of the workpiece is at a higher temperature relative to a second portion of the workpiece. As shown in FIG. 4 for instance, the data obtained at (610) can include data indicative of a first temperature associated with the first portion 131 of the workpiece 120 and of a second temperature associated with the second portion 132 of the workpiece 120. The data can indicate that the first portion 131 of the workpiece 120 is at a higher temperature relative to the second portion 132 of the workpiece 120.

At (630a), the method 600 can include adjusting a position of a reflector to reduce an amount of radiation directed onto the first portion. In certain embodiments, a plurality of reflectors 160 (e.g., mirrors) can be configured to direct radiation emitted from the radiative heating sources 150 toward the workpiece 120 and/or workpiece support 112. The plurality of reflectors 160 can include an array of controllable reflectors 161, which are positioned, for instance, to heat different zones, such as reflection heat zones 360, of the workpiece 120. In a first position, for instance, the controllable reflector 161 can direct radiation 461 onto the first portion 131 of the workpiece 120. In a second position, the controllable reflector 161 can direct radiation 461 onto the second portion 132 of the workpiece 120. As the workpiece increases in temperature, the data obtained at (610) can indicate at (620a) that the first portion 131 of the workpiece 120 is at a higher temperature relative to the second portion 132 of the workpiece 120. The controller 190 can control the controllable reflector 161 to adjust from the first position to the second position such that the second position reduces an amount of radiation that the controllable reflector 161 directs onto the first portion 131 of the workpiece 120.

At (620b), the method 600 can include determining that a first portion of the workpiece is at a lower temperature relative to a second portion of the workpiece. For example, the data obtained at (610) can indicate that the first portion 131 of the workpiece 120 is at a lower temperature relative to the second portion 132 of the workpiece 120.

At (630b), the method 600 can include adjusting a position of a reflector to increase an amount of radiation directed onto the first portion. In the first position, for instance, the controllable reflector 161 can direct radiation 461 onto the first the portion 131 of the workpiece 120. In the second position, the controllable reflector 161 can direct radiation 461 onto the second portion 132 of the workpiece 120. As the workpiece increases in temperature, the data obtained at (610) can indicate at (620b) that the first portion 131 of the workpiece 120 is at a lower temperature relative to the second portion 132 of the workpiece 120. The controller 190 can control the controllable reflector 161 to adjust from the second position to the first position such that the first position increases the amount of radiation that the controllable reflector 161 directs onto the first portion 131 of the workpiece 120.

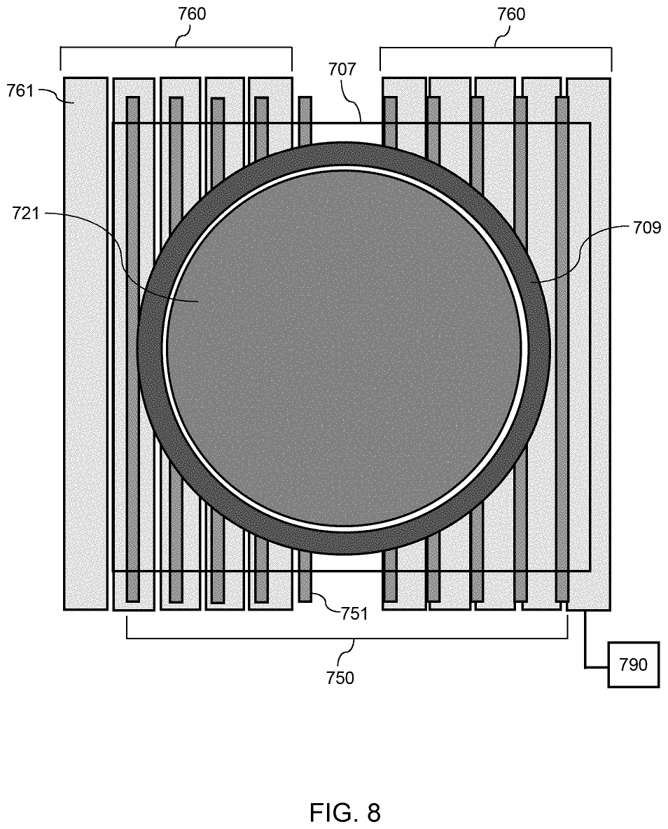

Referring now to FIGS. 7-8, a workpiece processing apparatus is provided according to embodiments of the present disclosure. For instance, a workpiece processing apparatus 700 can have a rotation system configured to rotate a workpiece support 712 while a vacuum is maintained in a processing chamber 705. In particular, FIG. 7 depicts the workpiece support 712 supporting a workpiece 720 disposed in the processing chamber 705. One or more radiative heating sources 750 are disposed on a second side of the processing chamber 705, such as on the bottom side of the processing chamber 705 as shown. A dielectric window 707 is disposed between the radiative heating sources 750 and the workpiece support 712.

As depicted in FIG. 7, the workpiece processing apparatus 700 can include one or more sensors, such as pyrometers 767,768, configured to obtain data indicative of a temperature profile associated with the workpiece 720. For example, the pyrometers 767,768 can be configured to measure radiation emitted by the workpiece at a wavelength within a temperature measurement wavelength range. The wavelength can be or include a wavelength to which transparent regions 776 of the dielectric window 707 are transparent and/or opaque regions 775 of the dielectric window 707 are opaque. The data obtained via the pyrometers 767,768 can include a plurality of temperature measurements. Furthermore, each temperature measurement of the plurality of temperature measurements can be associated with different locations across the surface of the workpiece 720. It should be appreciated that coupled with a wafer rotation, the data obtained via the pyrometers 767,768, which are stationary, can indicate non-uniformity in the temperature profile associated with the surface of the workpiece 720.

In some embodiments, the one or more sensors of the workpiece processing apparatus 700 includes one or more emitters 765 and one or more receivers 766 configured to obtain data indicative of a temperature profile associated with the workpiece 720. The emitters 765 can be configured to emit a signal (indicated generally by dashed lines) that reflects off the workpiece 720. The reflected signal (indicated generally by dashed lines) can be received via the receivers 766 of the device. It should be appreciated that a controller 790 of the workpiece processing apparatus 700 can be configured to determine reflectivity of the workpiece based, at least in part, on a difference between one or more parameters (e.g., phase, amplitude) of the signal emitted by emitters 765 and the reflected signal received via the receivers 766. In some embodiments, the temperature profile of the workpiece 720 can be calculated based on radiation emitted by workpiece 720 in combination with the reflectivity of workpiece 720.

The workpiece processing apparatus 700 can include a gas delivery system 755 configured to deliver process gas to the processing chamber 705, for instance, via a gas distribution channel 740 or other distribution system (e.g., showerhead). For example, process gases can be delivered by the distribution channel 740 and pass through one or more gas distribution plates 756 to more uniformly and evenly distribute gas in the processing chamber 705. The gas delivery system 755 can include a plurality of feed gas lines 759. The feed gas lines 759 can be controlled using valves 758 and/or gas flow controllers 785 to deliver a desired amount of gases into the processing chamber 705 as process gas. The gas delivery system 755 can be used for the delivery of any suitable process gas. One or more exhaust ports 921 disposed in the processing chamber 705 are configured to pump gas out of the processing chamber 705, such that a vacuum pressure can be maintained in the processing chamber 705.

The workpiece processing apparatus 700 can further include a rotation shaft 710 that passes a through dielectric window 707 and is configured to support the workpiece support 712 in the processing chamber 705. For example, the rotation shaft 710 is coupled on one end to the workpiece support 712 and is coupled about the other end to a rotation device (not shown in FIG. 7) capable of rotating the rotation shaft 710 360°. For instance, during thermal processing of the workpiece 720, the workpiece 720 can be continually rotated such that radiation emitted by the radiative heating sources 750 can evenly heat the workpiece 720. In some embodiments, rotation of the workpiece 720 forms radial heating zones on the workpiece 720, which can help to provide a good temperature uniformity control during the heating cycle.

In certain embodiments, it will be appreciated that a portion of the rotation shaft 710 is disposed in the processing chamber 705 while another portion of the rotation shaft 710 is disposed outside the processing chamber 705 in a manner such that a vacuum pressure can be maintained in the processing chamber 705. For example, a vacuum pressure may need to be maintained in the processing chamber 705 while the workpiece 720 is rotated during thermal processing. Accordingly, the rotation shaft 710 is positioned through the dielectric window 707 and in the processing chamber 705, such that the rotation shaft 710 can facilitate rotation of the workpiece 720 while a vacuum pressure is maintained in the processing chamber 705.

The workpiece processing apparatus 700 can include one or more radiative heating sources 750. In some embodiments, one of the radiative heating sources 750 can be disposed about a second side of the processing chamber 705, such as the bottom side of the processing chamber. Accordingly, radiative heating sources 750 can emit radiation onto a surface, such as a second surface, such as a back side, of the workpiece 720.

As shown in FIG. 7, the workpiece processing apparatus 700 can include directive elements, such as, for example, a plurality of reflectors 760 (e.g., mirrors). In some embodiments, the plurality of reflectors 760 can be disposed about a second side of the processing chamber 705, such as the bottom side of the processing chamber. As shown in FIG. 7, the radiative heating sources 750 can be positioned between the workpiece 720 and the plurality of reflectors 760. For instance, the radiative heating sources 750 can be disposed at a first distance from a back side of the workpiece, and the plurality of reflectors 760 can be disposed at a second distance from the back side of the workpiece such that the second distance is greater than the first distance. In some embodiments, the plurality of reflectors 760 can direct radiation toward the workpiece 720 and/or workpiece support 712 to heat the workpiece 720. For example, the plurality of reflectors 760 can direct radiation emitted from the radiative heating sources 750 onto a surface, such as the back side, of the workpiece 720.

As depicted in FIG. 8, the radiative heating sources 750 can be disposed with respect to the plurality of reflectors 760 to increase uniform application of radiation to the workpiece 720. In particular, FIG. 8 depicts a top view of the workpiece 720 with a top surface, such as a front side 721, of the workpiece 720 shown and with the dielectric window 707 disposed underneath the workpiece 720. In some embodiments, the radiative heating sources 750 can include an array of heat lamps, such as heat lamp 751, configured to emit thermal radiation toward a surface, such as a back side, of workpiece 720 to heat workpiece 720. Portions of the radiative heating sources 750 can be separated to provide a space for the rotation shaft 710 to couple to an end of the workpiece support 712. In some embodiments, the plurality of reflectors 760 can include an array of controllable reflectors 761 configured to direct radiation emitted by the radiative heating sources 750 toward the workpiece 720. Portions of the plurality of reflectors 760 can be separated to provide a space for the rotation shaft 710 to couple to an end of the workpiece support 712. In some embodiments, one or more of the controllable reflectors 761 can be connected to the controller 790 via a connection line or other suitable wired and/or wireless interface.

As further illustrated in FIG. 8, the radiative heating sources 750 can be in a generally parallel relationship, such as within 20 degrees of parallel, such as within 5 degrees of parallel, such as within 0.1 degrees of parallel, to the plurality of reflectors 760. For example, both the radiative heating sources 750 and the plurality of reflectors 760 can extend in a first direction. Such a generally parallel relationship between the radiative heating sources 750 and the plurality of reflectors 760 allows for an increased amount of radiation to be directed toward the portion of the workpiece support 712 to which the rotation shaft 710 is coupled.

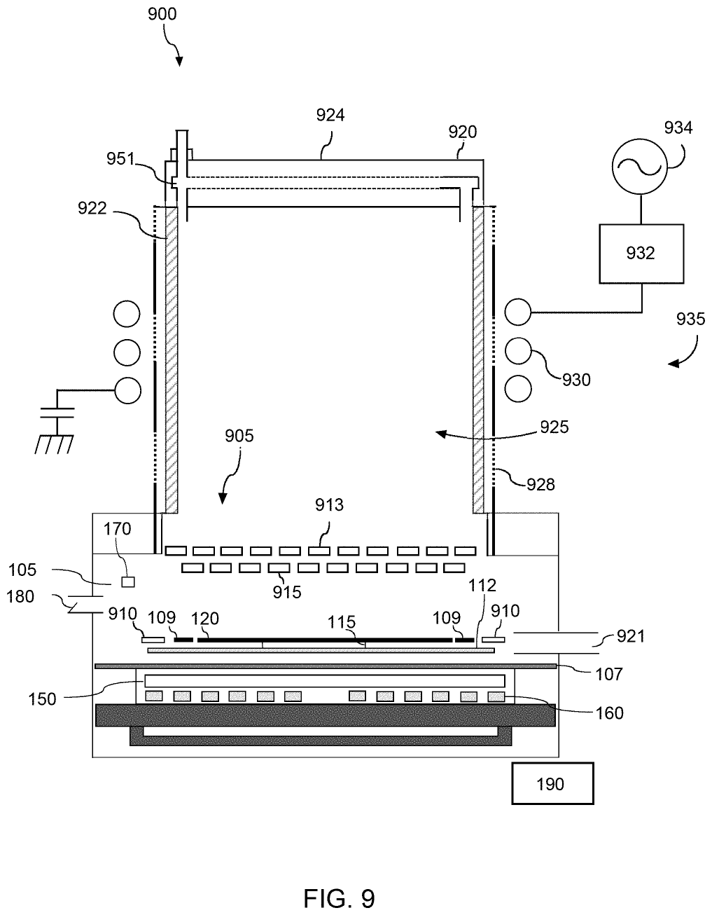

FIG. 9 depicts an example workpiece processing apparatus 900 that can be used to perform processes according to example embodiments of the present disclosure. For instance, the workpiece processing apparatus 100 of FIG. 1 can be configured to perform processes depicted in FIG. 9. As further illustrated in FIG. 1, for example, FIG. 9 depicts a processing chamber 105 including a workpiece support 112 or pedestal operable to hold and/or support, such as by support pins 115, a workpiece 120 to be processed. One or more radiative heating sources 150 are disposed on a second side of the processing chamber 105, such as on the bottom side of the processing chamber 105 as shown. A dielectric window 107 is disposed between the radiative heating sources 150 and the workpiece support 112. The workpiece processing apparatus 900 can further include a thermal camera 170 (e.g., infrared camera) configured to obtain thermal image data (e.g., infrared image data) indicative of a temperature profile associated with the workpiece 120.

According to example embodiments of the present disclosure, the workpiece processing apparatus 900 can include a controller 190 configured to adjust one or more positions of a plurality of reflectors 160 via a connection line (depicted in FIG. 2) or other suitable wired and/or wireless interface.

In some embodiments, the workpiece processing apparatus 100 can comprise a plasma source 935 configured to generate a plasma from the one or more process gases in a plasma chamber 920. As illustrated, the workpiece processing apparatus 100 includes a processing chamber 105 and a plasma chamber 920 that is separated from the processing chamber 105. In this example illustration, a plasma is generated in plasma chamber 920 (i.e., plasma generation region) by an inductively coupled plasma source 935 and desired species are channeled from the plasma chamber 920 to the surface of workpiece 120 through a separation grid assembly 905. In some embodiments, process gas exposed to the workpiece 120 can flow around either side of the workpiece 120 and can be evacuated from the processing chamber 105 via one or more exhaust ports 921. One or more pumping plates 910 can be disposed around the outer perimeter of the workpiece 120 to facilitate process gas flow. Isolation door 180, when open, allows entry of the workpiece 120 to the processing chamber 105 and, when closed, allows the processing chamber 105 to be sealed, such that a vacuum pressure can be maintained in the processing chamber 105 during thermal processing of workpiece 120.

Aspects of the present disclosure are discussed with reference to an inductively coupled plasma source for purposes of illustration and discussion. Those of ordinary skill in the art, using the disclosures provided herein, will understand that any plasma source (e.g., inductively coupled plasma source, capacitively coupled plasma source, etc.) can be used without deviating from the scope of the present disclosure.

The plasma chamber 920 includes a dielectric side wall 922 and a ceiling 924. The dielectric side wall 922, ceiling 924, and separation grid 905 define a plasma chamber interior 925. Dielectric side wall 922 can be formed from a dielectric material, such as quartz and/or alumina. Dielectric side wall 922 can be formed from a ceramic material. The inductively coupled plasma source 935 can include an induction coil 930 disposed adjacent the dielectric side wall 922 about the plasma chamber 920. The induction coil 930 is coupled to an RF power generator 934 through a suitable matching network 932. The induction coil 930 can be formed of any suitable material, including conductive materials suitable for inducing plasma within the plasma chamber 920. Process gases can be provided to the chamber interior 925 from a gas supply and annular gas distribution channel 951 or other suitable gas introduction mechanism. When the induction coil 930 is energized with RF power from the RF power generator 934, a plasma can be generated in the plasma chamber 920. In a particular embodiment, the workpiece processing apparatus 900 can include an optional grounded Faraday shield 928 to reduce capacitive coupling of the induction coil 930 to the plasma. The grounded Faraday shield 928 can be formed of any suitable material or conductor, including materials similar or substantially similar to the induction coil 930.

As shown in FIG. 9, the separation grid 905 separates the plasma chamber 920 from the processing chamber 105. The separation grid 905 can be used to perform ion filtering from a mixture generated by plasma in the plasma chamber 920 to generate a filtered mixture. The filtered mixture can be exposed to the workpiece 120 in the processing chamber 105. In some embodiments, the separation grid 905 can include a first grid plate 913 and a second grid plate 915 that are spaced apart in parallel relationship to one another.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A workpiece processing apparatus for processing a workpiece, the workpiece processing apparatus comprising:
a processing chamber, having a first side and a second side opposite from the first side of the processing chamber;
a gas delivery system configured to deliver one or more process gases to the processing chamber;
one or more exhaust ports for removing gas from the processing chamber such that a vacuum pressure can be maintained;
a workpiece support disposed within the processing chamber, the workpiece support configured to support a workpiece, wherein a back side of the workpiece faces the workpiece support;
one or more radiative heating sources configured on the second side of the processing chamber, the one or more radiative heating sources configured at a first distance from the back side of the workpiece, the one or more radiative heating sources configured to heat the workpiece from the back side of the workpiece;
a dielectric window disposed between the workpiece support and the one or more radiative heating sources;
a plurality of reflectors configured on the second side of the processing chamber at a second distance from the back side of the workpiece, the second distance being greater than the first distance; and
a control system configured to control one or more positions of the plurality of reflectors.

2. The workpiece processing apparatus of claim 1, wherein the one or more radiative heating sources are disposed in a generally perpendicular relationship to the plurality of reflectors, the one or more radiative heating sources extend in a first direction and the plurality of reflectors extend in a second direction orthogonal to the first direction.

3. The workpiece processing apparatus of claim 1, wherein the control system is configured to:
obtain data indicative of a temperature profile associated with the workpiece; and
control the one or more positions of the plurality of reflectors based at least in part on the data indicative of the temperature profile.

4. The workpiece processing apparatus of claim 3, further comprising:
one or more sensors configured to obtain the data indicative of the temperature profile associated with the workpiece.

5. The workpiece processing apparatus of claim 4, wherein the one or more sensors comprise a thermal camera, and wherein the data comprises thermal image data.

6. The workpiece processing apparatus of claim 1, wherein the workpiece support is stationary.

7. The workpiece processing apparatus of claim 3, wherein when the data indicates a first portion of the workpiece is at a higher temperature relative to a second portion of the workpiece, the control system is configured to control the one or more positions of at least one reflector of the plurality of reflectors to adjust from a first position to a second position such that the second position reduces an amount of radiation the at least one reflector directs from the one or more heat sources onto the first portion of the workpiece.

8. The workpiece processing apparatus of claim 3, wherein when the data indicates a first portion of the workpiece is at a lower temperature relative to a second portion of the workpiece, the control system is configured to control the one or more positions of at least one reflector of the plurality of reflectors to adjust from a first position to a second position such that the second position increases an amount of radiation the at least one reflector directs from the one or more radiative heating sources onto the first portion of the workpiece.

9. The workpiece processing apparatus of claim 1, wherein the one or more radiative heating sources comprises one or more heat lamps, and wherein the workpiece support comprises quartz, and the dielectric window comprises quartz.

10. The workpiece processing apparatus of claim 1, further comprising a plasma source configured to generate a plasma from the one or more process gases in a plasma chamber.

11. A method for controlling operation of a workpiece processing apparatus comprising one or more radiative heating sources positioned between a workpiece disposed on a workpiece support and a plurality of reflectors positioned within a processing chamber, the method comprising:
admitting, by a gas delivery system of the workpiece processing apparatus, one or more process gases into the processing chamber;
maintaining a vacuum pressure in the processing chamber;
emitting, by the one or more radiative heating sources of the workpiece processing apparatus, radiation to heat at least a portion of the workpiece;
obtaining, by a controller of the workpiece processing apparatus, data indicative of a temperature profile associated with the workpiece; and
controlling, by the controller, one or more positions of a plurality of reflectors based, at least in part, on the data indicative of the temperature profile.

12. The method of claim 11, wherein when a first portion of the workpiece is at a higher temperature relative to a second portion of the workpiece, controlling the one or more positions of the plurality of reflectors comprises:
controlling, by the controller, the one or more positions of at least one reflector of the plurality of reflectors to adjust from a first position to a second position such that the second position reduces an amount of radiation the at least one reflector directs from the one or more heat sources onto the first portion of the workpiece.

13. The method of claim 11, wherein when a first portion of the workpiece is at a lower temperature relative to a second portion of the workpiece, controlling the one or more positions of the plurality of reflectors comprises:
controlling, by the controller, the one or more positions of at least one reflector of the plurality of reflectors to adjust from a first position to a second position such that the second position increases an amount of radiation the at least one reflector directs from the one or more heat sources onto the first portion of the workpiece.

14. The method of claim 11, wherein obtaining data indicative of a temperature profile associated with the workpiece comprises obtaining, by the controller, the data via a thermal camera of the workpiece processing apparatus, and wherein the data comprises thermal image data.

15. The method of claim 11, wherein obtaining data indicative of a temperature profile associated with the workpiece comprises obtaining, by the controller, the data via a pyrometer of the workpiece processing apparatus.

16. The method of claim 11, further comprising:
maintaining a position of the workpiece support such that the workpiece support does not rotate in the workpiece processing apparatus.

17. The method of claim 11, wherein emitting, by the one or more radiative heating sources, a radiation comprises emitting radiation from one or more heat lamps.

18. A workpiece processing apparatus for processing a workpiece, the workpiece processing apparatus comprising:
a processing chamber, having a first side and a second side opposite from the first side of the processing chamber;
a gas delivery system configured to deliver one or more process gases to the processing chamber;
one or more exhaust port for removing gas from the processing chamber such that a vacuum pressure can be maintained;
a workpiece support disposed within the processing chamber, the workpiece support configured to support a workpiece, wherein a back side of the workpiece faces the workpiece support;
a rotation system configured to rotate the workpiece support;
one or more radiative heating sources configured on the second side of the processing chamber, the one or more radiative heating sources configured at a first distance from the back side of the workpiece, the one or more radiative heating sources configured to heat the workpiece from the back side of the workpiece;
a dielectric window disposed between the workpiece support and the one or more radiative heating sources;
a plurality of reflectors configured on the second side of the processing chamber at a second distance from the back side of the workpiece, the second distance being greater than the first distance, the plurality of reflectors disposed in a generally parallel relationship to the one or more radiative heating sources;
one or more sensors configured to obtain data indicative of a temperature profile associated with the workpiece; and
a control system configured to control one or more positions of the plurality of reflectors.

19. The workpiece processing apparatus of claim 18, wherein the data obtained from the one or more sensors comprises a plurality of temperature measurements, each temperature measurement associated with a different location on a surface of the workpiece.

20. The workpiece processing apparatus of claim 18, wherein the control system is configured to:
control the one or more positions of at least one of the plurality of reflectors based, at least in part, on the data indicative of the temperature profile associated with the workpiece.
